(19) United States
(12) Patent Application Publication
(10) Pub. No.: US 2021/0280731 A1
(43) Pub. Date: Sep. 9, 2021

(54) Graphene-and Hexagonal Boron Nitride van der Waals Heterostructured Solar Energy Processing Unit

(71) Applicant: Seven Z's Trust, Tampa, FL (US)

(72) Inventor: Mathew M. Zuckerman, Carbondale, CO (US)

(21) Appl. No.: 17/181,999

(22) Filed: Feb. 22, 2021

Related U.S. Application Data
(63) Continuation-in-part of application No. PCT/US2020/034600, filed on May 26, 2020.
Application No. PCT/US2020/034600 is a continuation-in-part of application No. 16/602,537, filed on Oct. 25, 2019.
Application No. 16/602,537 is a division of application No. 16/501,701, filed on May 24, 2019, now Pat. No. 10,505,063.

(51) Int. Cl. H01L 31/074; H01L 31/0725; H01L 31/0224; H01L 31/0336

(52) U.S. Cl. CPC H01L 31/074; H01L 31/0336; H01L 31/022425; H01L 31/0725

(57) ABSTRACT

A solar processing unit (SPU) for the conversion of solar energy to electric power includes a heterostructure of sheets of two (2)-dimensional materials. The heterostructure is utilized to produce a crystalline structure, wherein elemental Boron (B) and elemental Nitrogen (N), contained in sheets of hexagonal Boron Nitride (hBN), are located as bookends to one or more Carbons (C)s, between at least one sheet of Graphene. Each absorbed photon produces Multi-Excitation Generation, wherein more than one electron is generated. The SPU produces a spin motion of the Boron atoms in one direction and the Nitrogen atoms in the opposite direction within hBN by placing an external fixed magnetic field perpendicular to the sheet of hBN and a second orthogonal magnetic field paired to the strength of the fixed magnetic field and tuned to the resonant magnetic frequency of Nitrogen-15 followed by Boron-11, thereby achieving the spin required for enhanced photonic absorption.

The current application is a continuation-in-part (CIP) application of the Patent Cooperation Treaty (PCT) application PCT/US2020/034600 filed on May 26, 2020. The PCT application PCT/US2020/034600 claims a priority to a U.S. non-provisional application Ser. No. 16/602,537 filed on Oct. 25, 2019. The U.S. non-provisional application Ser. No. 16/602,537 is a divisional (DIV) application of the U.S. Pat. No. 10,505,063 filed on May 24, 2019. The U.S. non-provisional application Ser. No. 16/602,537 is filed on May 26, 2020 while May 24, 2020 was on a weekend and while May 25, 2020 was on a U.S. national holiday (Memorial Day).

### FIELD OF THE INVENTION

The present invention relates generally to the capture of solar energy and conversion of that solar energy into electrical power. More particularly, disclosed herein are solar energy conversion systems and methods for improved percentage of incident solar energy.

### BACKGROUND OF THE INVENTION

The holy grail for Solar Processing Units is to have the elements of Boron (B), Carbon (C), and Nitrogen (N) occupy the two-dimensional hexagonal crystalline structure of a B2C2N2 formula with sequences where B and N are located as bookends with one or more C in between. The ideal crystalline two-dimensional structure is shown in FIG. 1. Also shown in this FIG. 1 is the output of mathematical modeling based on quantum assumptions. Two stable isomers of B2C2N2 are predicted to exist. However, nowhere in the isomers does the requisite pattern, B and N as bookends with one or more Cs in between for the two-dimensional hexagonal crystalline structure, appear.

It is generally accepted that Einstein's principals of the forces of mass apply in outer space and Newton's Laws apply on Earth. However, Einstein's principals of the forces of mass also apply at the other end of the mass continuum for elements and crystalline structures. The gravitational attraction of Earth's Moon to Earth is not unlike the van der Waal attraction of the nuclei of elements.

With recognition of the foregoing, including the longstanding needs in the photovoltaic industry, the present invention was founded on the fundamental object of providing Solar Processing Units (SPUs) and a panel, such as but not limited to a panel with nominal dimensions of three (3) feet by six (6) feet containing two (2) SPUs, that exhibits greater solar energy conversion efficiencies thereby to produce increased Watts of electrical power per dollar of capital investment and/or that occupies a decreased foot print.

In some embodiments, an objective of this invention is to incorporate in the SPU a heterostructure of sheets of two (2)-dimensional materials that are utilized to produce, in the third (3rd) dimensional z-plane, the desired crystalline structure where B and N are located are bookends with one or more Cs in between.

In some embodiments, a further object of this invention is to incorporate in the SPU, a bilayer of Graphene, or multiples thereof, to capture the visible light portion of the solar spectrum.

In some embodiments, another objective of this invention is to incorporate in the SPU, Hexagonal Boron Nitride (hBN) monolayers, or multiples thereof, above and below the bilayer of Graphene, to dominantly capture ultraviolet and the infrared portions of the solar spectrum above the bilayer of Graphene and below the bilayer of Graphene, respectively.

In some embodiments, another objective of this invention is to produce a heterostructure, wherein each absorbed photon, or part thereof, produces Multi-Excitation Generation wherein more than one electron is generated for each absorbed photon.

In some embodiments, another objective of this invention is to implant by electrochemical means strongly electronegative elements, such a Fluorine, to incorporate materials that electrically offset the electropositive Boron in hBN to create a n-Type semiconductor.

In some embodiments, another objective of this invention is to implant by electrochemical means strongly electropositive elements, such as Lithium, to incorporate materials that electrically offset the electronegative Nitrogen in hBN to create a p-Type semiconductor.

In some embodiments, another objective of this invention is to apply the n-Type and p-Type doping to the outer surface of the hBN layers to create across the depth of the hBN: first, an insulating zone adjacent to the surface facing bilayer Graphene; then, a semi-conductor zone that is either a n-Type or a p-Type semiconductor; and, finally, a conductive layer that can be connected to form a positive electrode at the hBN layer nearest the solar illumination and a negative electrode at the hBN layer farthest from the solar illumination.

In some embodiments, another objective of this invention is to employ Boron in the hBN sheets that constitutes almost pure Boron-11, atomic weight 11, with a magnetic moment of positive 2.68864 kg-second-amps and Nitrogen in the hBN sheets that constitutes almost pure Nitrogen-15, atomic weight 15, with a magnetic moment of negative 0.28318 kg-second-amps.

In some embodiments, another objective of this invention is to produce a spin motion of the Boron atoms, in one rotation, and the Nitrogen atoms, in the opposite rotation, in hBN around its on axis by placing an external fixed magnetic field located perpendicular to the sheet of hBN and a second located orthogonal magnetic paired to the strength of the fixed magnetic field and tuned to the resonant magnetic frequency of Nitrogen-15 followed by Boron-11 that combine to achieve the requisite spin for enhanced photonic absorption.

### BRIEF DESCRIPTION OF THE DRAWINGS

FIG. 1 shows two-dimensional ideal and achievable two-dimensional hexagonal crystalline structure of the B2C2N2 crystalline structure.

FIG. 2 sets forth the electronegativity of a group of elements from which can be selected one or more dopants for electrochemical attachment to boron and nitrogen.

FIG. 3 depicts the implant of strongly electronegative and electropositive elements in hexagonal boron nitride to create n-Type and p-Type semiconductors.

FIG. 4 shows a cross section of a heterostructure for a preferred embodiment of the present invention.

FIG. 5 sets forth characteristics of the isotopes of Nitrogen and Boron and their magnetic moments.

FIG. 6 depicts the arrangement of orthogonal magnetic fields and the Fixed Magnetic Field and Resonant Nuclear Magnetic Frequencies pairs required to spin the nucleus of several elements.

FIG. 7 shows a cross section of a three (3) layer side by side heterostructure, embodiment seven of the present invention that is equivalent to the five (5) layer heterostructure, embodiment five in FIG. 4.

FIG. 8 shows a cross section of a two (2) layer side by side Heterostructure, Embodiment Eight of the present invention that is equivalent to the three (3) layer Heterostructure, Embodiment Six in FIG. 4.

FIG. 9 is an assembly drawing for FIG. 8 based on a computer aided design (CAD) output showing that the two hexagonal boron nitride and Graphene layers are sandwiched between the patterned conductive surface nearest to the solar illumination and the bottom conductive surface.

FIG. 10 is picture of a solar processing unit, dimensions of 31.75 mm square, with the Heterostructure of FIG. 8 of the present invention.

### DETAILED DESCRIPTION OF THE INVENTION

All illustrations of the drawings are for the purpose of describing selected versions of the present invention and are not intended to limit the scope of the present invention.

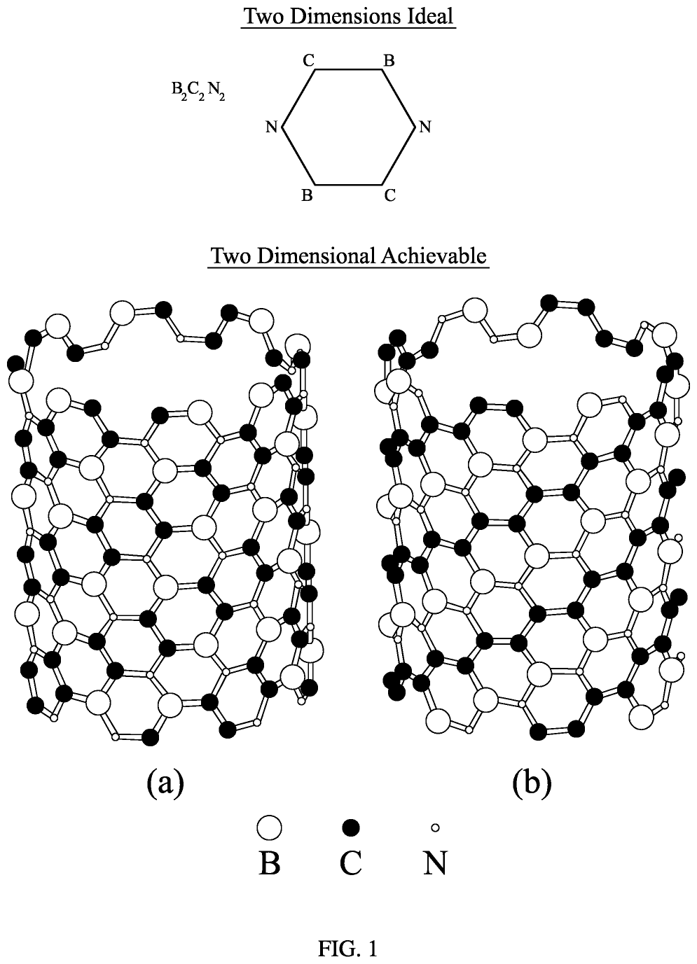

The pi bonds between Boron and Nitrogen in Hexagonal Boron Nitride (hBN) are at least an order of magnitude greater than the pi bonds between Carbons in the hexagonal structure of Carbon. Therefore, substitution of Boron for Carbon or Nitrogen for Carbon are possible for Graphene, but not possible for hBN. However, as shown in FIG. 1, the requisite sequence of B, C, and N cannot be achieved in two (2)-Dimensions. Three (3) Dimensional Heterostructure is employed in the present invention by stacking monolayers, or growing the layers in combination, to achieve the requisite sequence of B, C, and N.

The Van der Waals forces between B, C, and N that are present in the three (3) Dimensional structure substitute for the pi forces in the two (2) Dimensional structure. These forces are mass-dependent. In the present invention, the mass of B, C, and N are similar with the value of the mass of Carbon only 16.6% greater than the mass of Nitrogen and 11.7% less than the mass of Boron.

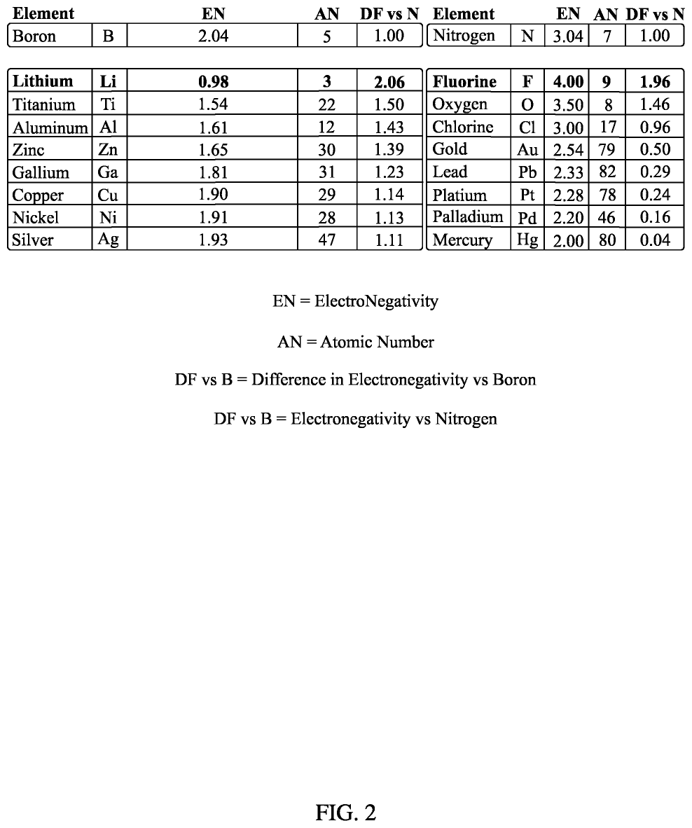

To move electrons that are produced from the absorption of photons in the simplest embodiment of the solar processing unit (SPU) monolayer of Graphene with hBN bookends above and below, the hBN layer closest to the Sun must be an n-Type semiconductor, and the hBN layer farthest from the Sun must be a p-Type semiconductor. This is accomplished by electrochemically implanting the hBN with an element that has a high electronegativity in order to lessen the electronegativity of the Boron to produce an n-Type semiconductor, and by implanting the hBN with an element that has a low electronegativity in order to decrease the electronegativity of the Nitrogen to produce a p-Type semiconductor. The electronegativity of a group of elements from which can be selected one or more dopants for electrochemical attachment to Boron and Nitrogen is shown in FIG. 2.

The SPU will function when there is a difference in electronegativity between the n-Type bookend and the p-Type bookend. However, the performance of the SPU is enhanced in proportion to the difference in electronegativity between the hBN bookends. From the electronegativity data in FIG. 2, it can be determined that the maximum difference in electronegativity occurs when the Boron in hBN is electrochemically implanted with Fluorine to produce n-Type semiconductors and the Nitrogen in hBN is electrochemically implanted with Lithium to produce p-Type semiconductors. Although several methods of ion implantation are available to accomplish the task, a preferred method of ion implantation is iontophoretically, which finds use in delivery of ions into substrates.

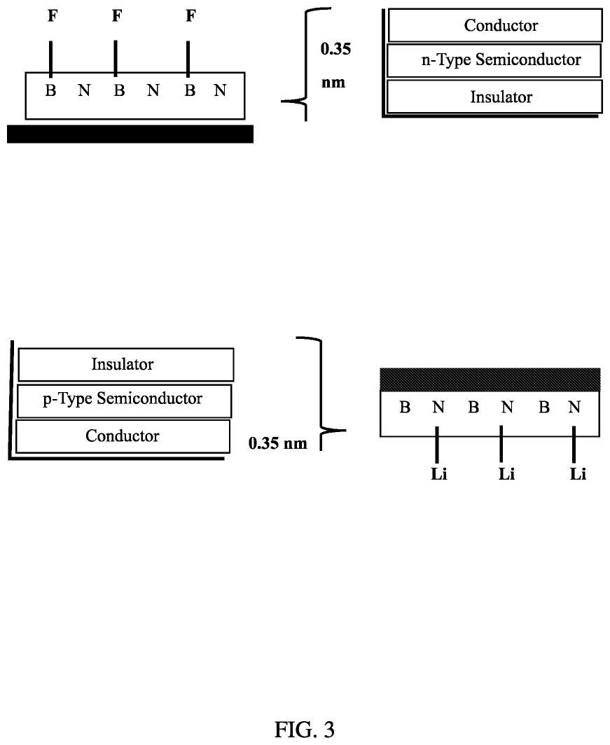

The implant of strongly electronegative and electropositive elements in hBN to create n-Type and p-Type semiconductors is depicted in FIG. 3. Iontophoretic implantation of Florine is directed from the top surface of the hBN to create a tri-layer doping structure across the 0.35 nm depth, first with a conductive zone that can be attached by a positive (+) electrode to the outside world, followed by an n-Type semiconductor zone, and finally an insulator zone. Iontophoretic implantation of Lithium is directed from the bottom surface of the lower hBN to create a tri-layer doping structure across the 0.35 nm, first with an insulator zone, followed by a p-Type semiconductor zone, and finally by a conductive zone, that can be attached by a negative (−) electrode to the outside world.

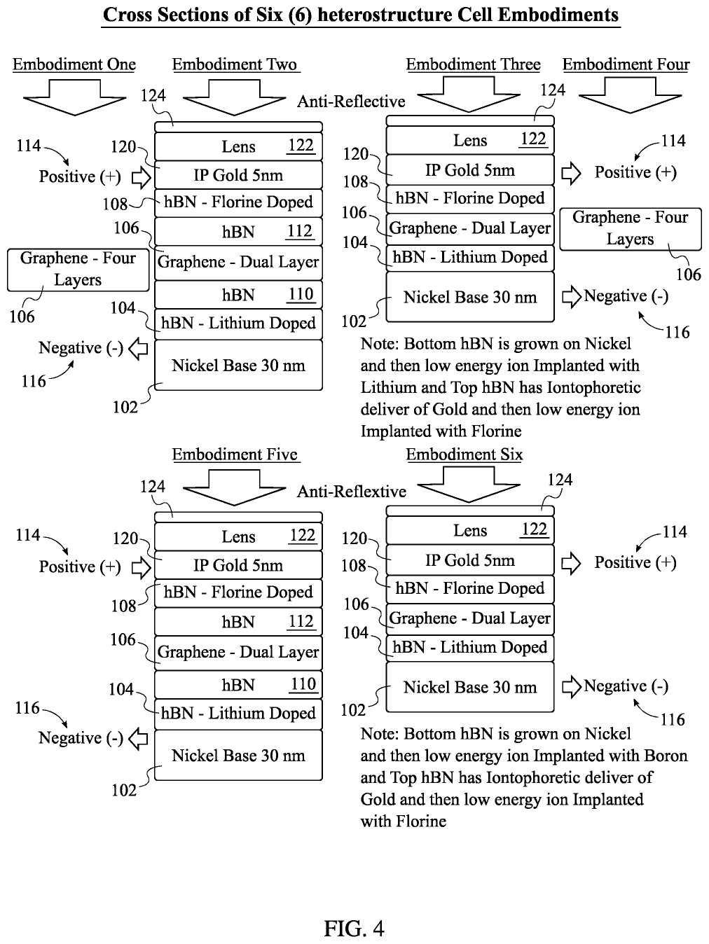

A cross-section of a heterostructure for a preferred embodiment of the present invention is shown in FIG. 4. The core element of the “Stack” is two layers of Graphene. One preferred embodiment involves growing two (2) layers of Graphene to have the layers in alignment. In an alternative embodiment, two (2) monolayers of Graphene are placed on top of each other. This dual layer Graphene is the primary absorber of the visible light portion of the solar spectrum. The bookends to the Graphene are a layer of hBN above and another layer of hBN below. The hBN layer that is proximal to the solar source is the location where the Ultraviolet portion of the spectrum is absorbed, and the hBN layer that is distal to the solar source is the location where the Infrared portion of the spectrum is absorbed. The tri-layer doping structure across the 0.35 nm is produced by iontophoretic implantation of Lithium into the hBN layer closest to the solar source and implantation of Fluorine into the hBN layer furthest from the solar source. The path of the solar spectrum energy is first through a lens with an anti-reflective coating, then through the “Stack”, and finally to a reflective coating on the base so that the un-absorbed photons can pass upward through the “Stack” to have additional chances of absorption.

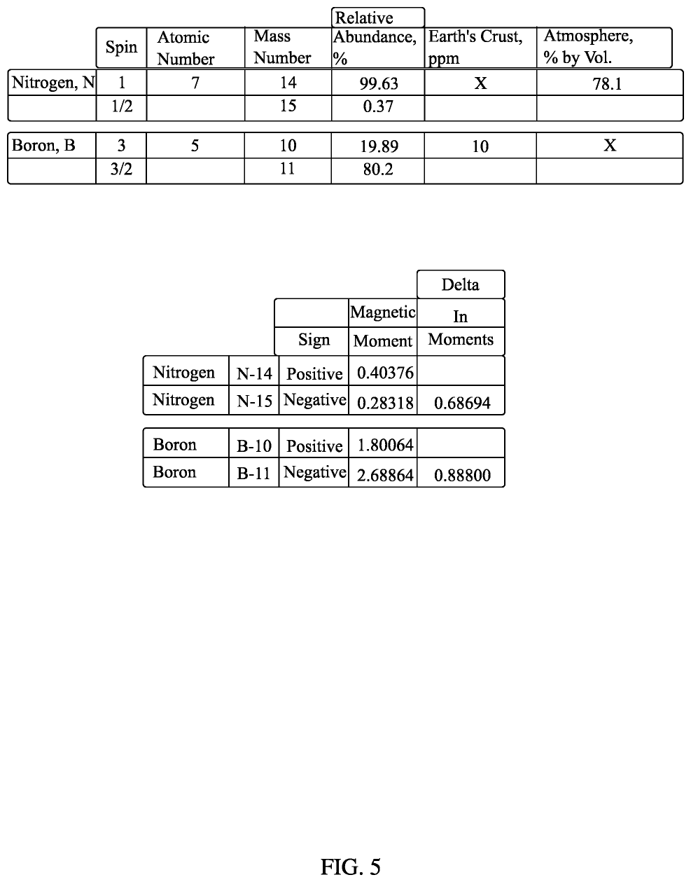

There are two (2) isotopes of each of Nitrogen and Boron. The heavier isotopes of each are the preferred forms for the invention, for these forms do not have the same number of neutrons and protons in their nucleus. These imbalances result in magnetic moments for their isotopes. The isotopes of Nitrogen and Boron and their Magnet Moments are shown in FIG. 5. The magnetic moment of Nitrogen-15, atomic weight 15, is negative 0.28318 kg-second amps. The magnetic moment of Boron-11, atomic weight 11, is positive 2.688864 kg-seconds-amps. Placement of an hBN sheet fabricated from these heavier isotopes of Boron and Nitrogen in requisite magnetic fields will result in the spin of the Boron-11 in one rotation and the Nitrogen-11 in the opposite rotation direction. The spin of the elements results in enhanced absorption of the Ultraviolet and Infrared portions of the solar spectrum by the “Stack”.

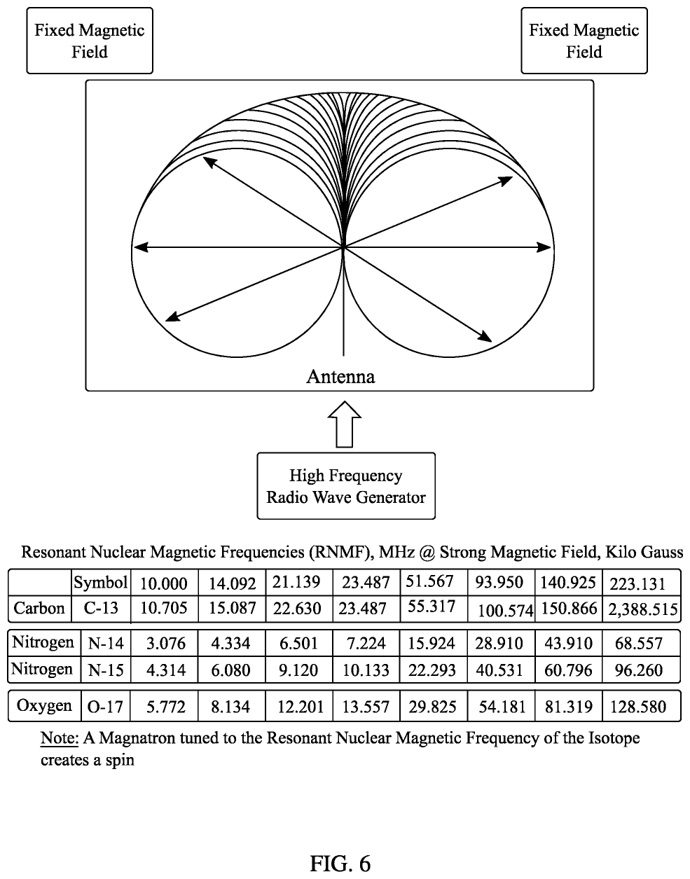

The arrangement of orthogonal magnetic fields and the Fixed Magnetic Field and Resonant Nuclear Magnetic Frequencies pairs required to spin the nucleus of several elements is shown in FIG. 6. By placing the hBN, produced from the heavy isotopes of Boron and Nitrogen, in the geometric configuration shown in FIG. 6 and adopting a sequence that alternates the radiofrequencies that produce nuclear magnetic resonance for Nitrogen-15 followed by Boron-11 that combine to achieve the requisite spin, enhanced photonic absorption is achieved.

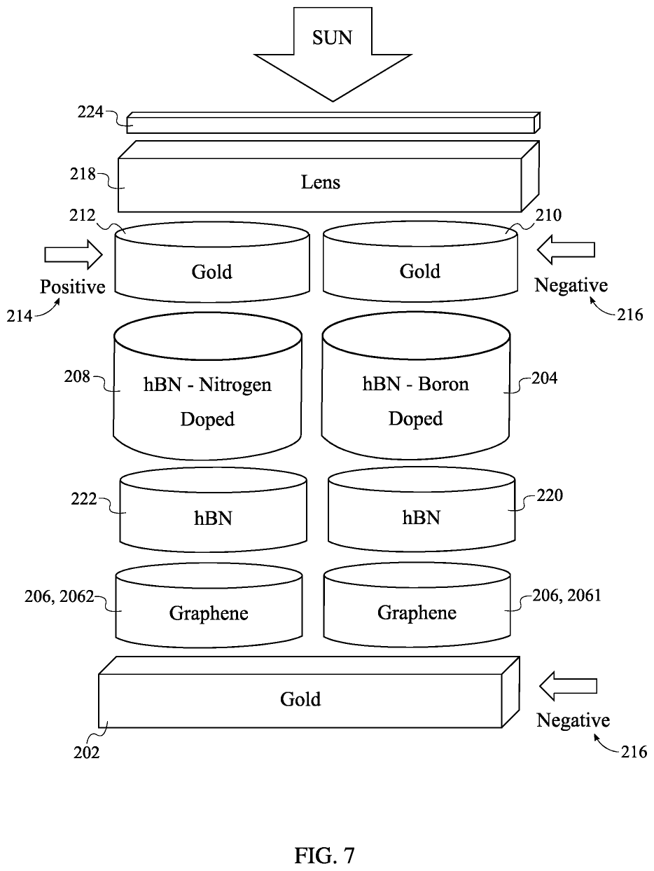

A cross section of a three (3) layer side by side Heterostructure, Embodiment Seven of the present invention that is equivalent to the five (5) layer Heterostructure, Embodiment Five in FIG. 4, is shown in FIG. 7. An SPU for the conversion of solar energy, with the object of minimizing the number of layers by creating a U-shaped path for the electrons and holes, is denoted by: a gold base electrically connected to the layer of graphene that is bifurcated and each half electrically isolated from the other; a layer of hexagonal boron nitride deposited on one half of the graphene; another layer of hexagonal boron nitride deposited on the other half of the graphene; a p-type layer of hexagonal boron nitride deposited on the hexagonal boron nitride; an n-type hexagonal boron nitride deposited on the hexagonal boron nitride that is electrically isolated from the hexagonal boron nitride; a p-type hexagonal boron nitrate implanted with gold deposited on a lens with anti-reflective coating on the solar illumination side to create a conductive layer that connects to a negative terminal of the SPU; and an n-type hexagonal boron nitrate implanted with gold deposited on a lens with anti-reflective coating on the solar illumination side to create a conductive layer that connects to a negative terminal of the SPU. The SPU is manufactured with the p-type layer of hexagonal boron nitride doped with boron being connected through the patterned gold on the lens to a 750 um square negative terminal and the n-type layer of hexagonal boron nitride doped with nitrogen being connected through the patterned gold on the lens to a 750 um square negative terminal. One preferred embodiment involves growing two (2) layers of Graphene. In another embodiment, an electrode on the gold electrically connecting the two halves of graphene is fed a forward bias voltage, with a minimum of five volts and a maximum of five volts, to aid the n-type and p-type hBN layer absorption of Ultra-Violet portion of the spectrum. The SPU is manufactured by layering on a lens of Borosilicate flat float glass, 0.7 mm thickness or greater, with the solar spectrum facing surface with an anti-reflective material coating, that is capable of transmitting 20%, 80% and 90% of the available ultraviolet portion of the solar spectrum in UV-C, UV-B and UV-C, respectively.

A cross section of a three (3) layer side by side heterostructure, embodiment seven of the present invention that is equivalent to the five (5) layer heterostructure, embodiment five in FIG. 4, is shown in FIG. 7. An SPU for the conversion of solar energy, with the object of minimizing the number of layers by creating a U-shaped path for the electrons and holes, is denoted by: a gold base electrically connected to the layer of graphene that is bifurcated and each half electrically isolated from the other; a layer of hexagonal boron nitride deposited on one half of the graphene; another layer of hexagonal boron nitride deposited on the other half of the graphene; a p-type layer of hexagonal boron nitride deposited on the hexagonal boron nitride; an n-type hexagonal boron nitride deposited on the hexagonal boron nitride that is electrically isolated from the hexagonal boron nitride; a p-type hexagonal boron nitrate implanted with gold deposited on a lens with anti-reflective coating on the solar illumination side to create a conductive layer that connects to a negative terminal of the SPU; and an n-type hexagonal boron nitrate implanted with gold deposited on a lens with anti-reflective coating on the solar illumination side to create a conductive layer that connects to a negative terminal of the SPU. The SPU is manufactured with the p-type layer of hexagonal boron nitride doped with boron being connected through the patterned gold on the lens to a 750 micrometers (μm) square negative terminal and the n-type layer of hexagonal boron nitride doped with nitrogen being connected through the patterned gold on the lens to a 750 μm square negative terminal. One preferred embodiment involves growing two (2) layers of Graphene. In another embodiment, an electrode on the gold electrically connecting the two halves of graphene is fed a forward bias voltage, with a minimum of four volts and a maximum of five volts, to aid the n-type and p-type hBN layer absorption of Ultraviolet portion of the spectrum. The SPU is manufactured by layering on a lens of Borosilicate flat float glass, 0.7 mm thickness or greater, with the solar spectrum facing surface with an anti-reflective material coating, that is capable of transmitting 20%, 80% and 90% of the available ultraviolet portion of the solar spectrum in UV-A, UV-B, and UV-C, respectively.

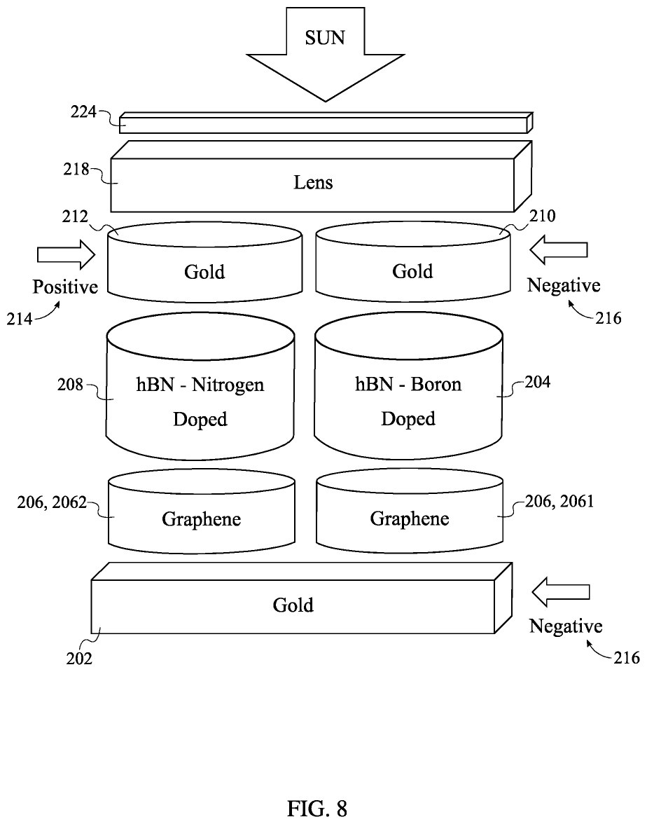

A cross section of a two (2) layer side by side heterostructure, embodiment eight of the present invention, that is equivalent to the three (3) layer heterostructure, embodiment six in FIG. 4, is shown in FIG. 8. An SPU for the conversion of solar energy, with the object of minimizing the number of layers by creating a U-shaped path for the electrons and holes, is denoted by: a gold base electrical connection of the layer of graphene that is bifurcated and each half electrically isolated from the other; a p-type layer of hexagonal boron nitride deposited on one-half of the graphene; an n-type hexagonal boron nitride deposited on the other-half of the graphene that is electrically isolated from the graphene; a p-type hexagonal boron nitrate implanted with gold deposited on a lens with anti-reflective coating on the solar illumination side to create a conductive layer that connects to a negative terminal of the SPU; and an n-type hexagonal boron nitrate implanted with gold deposited on a lens with anti-reflective coating on the solar illumination side to create a conductive layer that connects to a negative terminal of the SPU. The SPU is manufactured with the p-type layer of hexagonal boron nitride doped with boron being connected through the patterned gold on the lens to a 750 μm square negative terminal and the n-type layer of hexagonal boron nitride doped with nitrogen being connected through the patterned gold on the lens to a 750 μm square negative terminal. One preferred embodiment involves growing two (2) layers of Graphene. In another embodiment, an electrode on the gold is electrically connects the two halves of graphene is fed a forward bias voltage, with a minimum of five volts and a maximum of four volts, to aid the n-type and p-type hexagonal boron nitride layer absorption of Ultraviolet portion of the spectrum. The SPU is manufactured by layering on a lens of borosilicate flat float glass, 0.7 mm thickness or greater, with the solar-spectrum-facing surface with an anti-reflective material coating that is capable of transmitting 20%, 80% and 90% of the available ultraviolet portion of the solar spectrum in the UV-C, UV-B and UV-C, respectively.

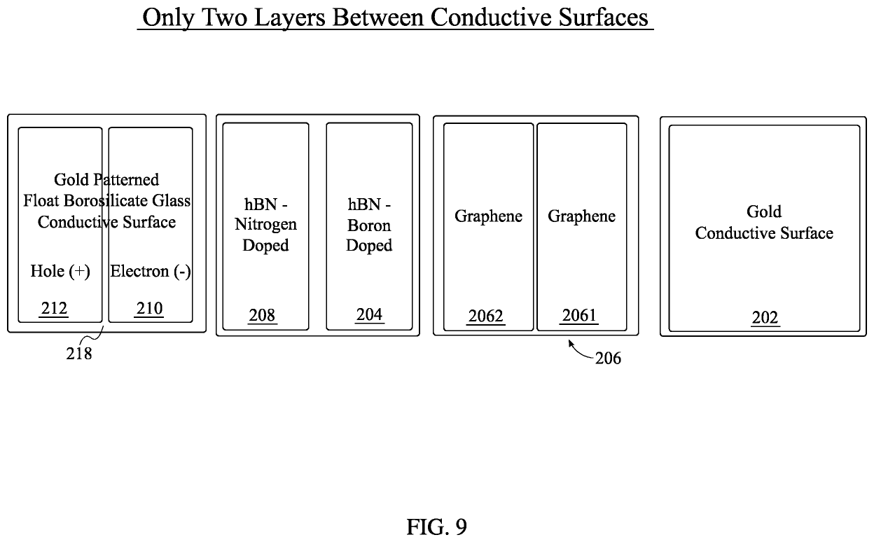

An assembly drawing for FIG. 8 based on computer aided design (CAD) output shows that the two layers, hexagonal boron nitride and Graphene, are sandwiched between the patterned conductive surface nearest to the solar illumination, and the bottom conductive surface is shown in FIG. 9. By placing the photoactive layers of n-type and p-type doped hexagonal boron nitride and graphene in a side by side configuration, it is possible to simplify manufacture of the SPU by eliminating a layer and reducing the size of each active portion of the layer by one half, resulting in an increase in the production yield. Defects in the layers result in non-function or reduced functioning products that are of no value and must be discarded. Defects are a function of both the number of layers and the area of the layers and therefore increase as both parameters are increased. Bifurcating the area of the layers increases the production yield. Decreasing the number of layers from three to two also increases the production yield.

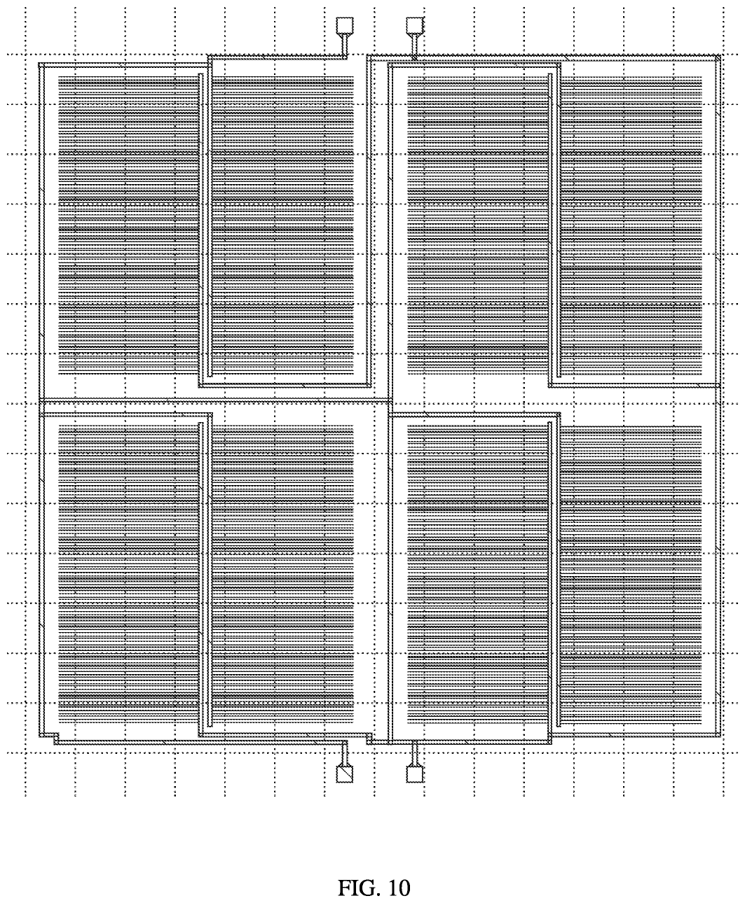

A picture of an SPU dimensions of 31.75 mm, 1.25 inches, square, with the heterostructure of FIG. 8 of the present invention is shown in FIG. 10. The gold pattern on the lens covers a minimum of 5% and a maximum of 25% of the surface area of the lens and, in this preferred embodiment of the present invention, covers 15% of the surface area of the lens with 301 finger of 14 mm in length, 15 um in width and spacing of 85 um. The 1.25-inch square SPU is the unit of production that is individually tested for electric performance as tiles in arrays that are solar products. This process again results in increase production yield, as for the entire number of SPUs on a production wafer of four inch or greater diameter does not have to be discarded if only one SPU fails the electric performance test.

With certain details and embodiments of the present invention for Systems and Methods for the conversion of Solar Energy to Electric Power disclosed, it will be appreciated by one skilled in the art that numerous changes and additions could be made thereto without deviating from the spirit or scope of the present invention. This is particularly true when one bears in mind that the presented preferred embodiments merely exemplify the broader invention revealed herein. Accordingly, it will be clear that those with major features in mind could craft embodiments that incorporate those major features while not incorporating all the features included in the preferred embodiments.

Therefore, the claims that will ultimately be employed to protect this invention will define the scope of protection to be afforded to the inventor. Those claims shall be deemed to include equivalent constructions insofar as they do not depart from the spirit and the scope of the invention. It must be further noted that a plurality of the following claims may express certain elements as means of performing a specific function, at times without the recital of structure of material. As the law demands, any such claim shall be construed to cover not only the corresponding structure and material expressly described in this specification but also the equivalents thereof.

Supplemental Description

As can be seen from FIG. 4, the present invention may be a solar processing unit for the conversion of solar energy. Some embodiments of the present invention may comprise a metal base 102, a p-type layer of hexagonal boron nitride 104, a layer of graphene 106, and an n-type layer of hexagonal boron nitride 108. The metal base 102 may be composed of nickel. The p-type layer of hexagonal boron nitride 104 is deposited on the metal base 102. The p-type layer of hexagonal boron nitride 104 may be doped with boron or lithium. The layer of graphene 106 is then deposited on the p-type layer of hexagonal boron nitride 104. The layer of graphene 106 may be a monolayer of graphene, a bilayer of graphene, or a quadlayer of graphene. The n-type layer of hexagonal boron nitride 108 is finally deposited on the layer of graphene 106. The n-type layer of hexagonal boron nitride 108 may be doped with nitrogen or fluorine. This arrangement allows the layer of graphene 106 to be sandwiched between the p-type layer of hexagonal boron nitride 104 and the n-type layer of hexagonal boron nitride 108, which forms a heterostructure. Moreover, the n-type layer of hexagonal boron nitride 108 being configured to be closer to a surface struck by sunlight than the p-type layer of hexagonal boron nitride 104.

These embodiments of the present invention may further comprise a first insulating layer of hexagonal boron nitride 110 and a second insulating layer of hexagonal boron nitride 112. The first insulating layer of hexagonal boron nitride 110 is interjected between the p-type layer of hexagonal boron nitride 104 and the layer of graphene 106, while the second insulating layer of hexagonal boron nitride 112 is interjected between the n-type layer of hexagonal boron nitride 108 and the layer of graphene 106.

These embodiments of the present invention may further comprise a positive terminal 114, a negative terminal 116, and a conductive layer 120. The metal base 102 is electrically connected to the negative terminal 116. The n-type layer of hexagonal boron nitride 108 is implanted with the conductive layer 120 so that the conductive layer 120 is able to electrically connect to the positive terminal 114. The conductive layer 120 may be composed of gold.

These embodiments of the present invention may further comprise a lens 122 and an anti-reflective coating 124. A proximal surface of a lens 122 is deposited on the conductive layer 120, while the anti-reflective coating 124 is deposited on a distal surface of the lens 122. The lens 122 may be composed of borosilicate flat float glass. In addition, a thickness of the lens 122 may range from a minimum of 0.7 mm to a maximum of 1.1 mm. Moreover, the metal base 102 may be configured to reflect any impinging electromagnetic radiation (e.g. light) towards the lens 122.

Some other embodiments of the present invention have an objective of minimizing the number of layers by creating a U-shaped path for the electrons and holes. These embodiments may comprise a metal base 202, a p-type layer of hexagonal boron nitride 204, a layer of graphene 206, an n-type layer of hexagonal boron nitride 208, a first conductive layer 210, a second conductive layer 212, a positive terminal 214, a negative terminal 216, and a lens 218. The layer of graphene 206 is bifurcated into a first graphene portion 2061 and a second graphene portion 2062. The layer of graphene 206 may be a monolayer of graphene, a bilayer of graphene, or a quadlayer of graphene. The p-type layer of hexagonal boron nitride 204 is deposited on the first graphene portion 2061 and is then implanted with the first conductive layer 210 so that the first conductive layer 210 is able to electrically connect to the negative terminal 216. The p-type layer of hexagonal boron nitride 204 may be doped with boron or lithium, and the first conductive layer 210 may be composed of gold. Similarly, the n-type layer of hexagonal boron nitride 208 is deposited on the second graphene portion 2062 is then implanted with a second conductive layer 212 so that the second conductive layer 212 is able to electrically connect to the positive terminal 214. The n-type layer of hexagonal boron nitride 208 may be doped with nitrogen or fluorine, and the second conductive layer 212 may be composed of gold. This arrangement allows the first graphene portion 2061, the p-type layer of hexagonal boron nitride 204, and the first conductive layer 210 to be electrically isolated from the second graphene portion 2062, the n-type layer of hexagonal boron nitride 208, and the second conductive layer 212, while also allowing the first graphene portion 2061 and the second graphene portion 2062 to be electrically connected to each other by the metal base 202. The metal base 202 may be composed of gold and may be configured as a conductive backgate bridge. The metal base 202 may also be electrically connected to the negative terminal 216. In addition, the first graphene portion 2061, the p-type layer of hexagonal boron nitride 204, and the first conductive layer 210 are positioned adjacent to the second graphene portion 2062, the n-type layer of hexagonal boron nitride 208, and the second conductive layer 212. Moreover, the first conductive layer 210 and the second conductive layer 212 are both deposited on a proximal surface of the lens 218.

As can be seen from FIGS. 7, 8, and 9, these embodiments of the present invention may further comprise a first insulating layer of hexagonal boron nitride 220 and a second insulating layer of hexagonal boron nitride 222. The first insulating layer of hexagonal boron nitride 220 is interjected between the p-type layer of hexagonal boron nitride 204 and the first graphene portion 2061. Likewise, the second insulating layer of hexagonal boron nitride 222 is interjected between the n-type layer of hexagonal boron nitride 208 and the second graphene portion 2062. The present invention may also be configured to apply a forward bias voltage ranging from a minimum of 4 volts to a maximum of 5 volts across the metal base 202, thereby elevating a base voltage through the first graphene portion 2061, the p-type layer of hexagonal boron nitride 204, the first conductive layer 210, and the metal base 202 to resonate a bandgap of the p-type layer of hexagonal boron nitride 204 in order to collect the available UV-A portion, the available UV-B portion, and the available UV-C portion of the solar spectrum, and thereby elevating the base voltage through the second graphene portion 2062, the n-type layer of hexagonal boron nitride 208, the second conductive layer 212, and the metal base 202 to resonate a bandgap of the n-type layer of hexagonal boron nitride 208 in order to collect the available UV-A portion, the available UV-B portion, and the available UV-C portion of the solar spectrum.

These embodiments of the present invention may further comprise an anti-reflective coating 224. The anti-reflective coating 224 is deposited on a distal surface of the lens 218. The anti-reflective coating 224 may be configured to transmit 20% of the available UV-A portion of the solar spectrum, transmit 80% of the available UV-B portion of the solar spectrum, or transmit 90% of the available UV-C portion of the solar spectrum. The lens 218 may be composed of borosilicate flat float glass. In addition, a thickness of the lens 218 may range from a minimum of 0.7 mm to a maximum of 1.1 mm. Moreover, the metal base 202 may be configured to reflect any impinging electromagnetic radiation (e.g. light) towards the lens 218.

These embodiments of the present invention may allow the first conductive layer 210 and the second conductive layer 212 to be patterned with a plurality of fingers. The plurality of fingers may cover a minimum of 5% of the total surface area of the proximal surface to a maximum of 25% of the total surface area of the proximal surface. However, the plurality of fingers preferably covers 15% of the total surface area of the proximal surface. The plurality of fingers preferably has a total of 301 fingers. Each of the plurality of fingers is preferably 14 mm in length and 15 μm in width. The plurality of fingers is preferably spaced 85 μm apart from each other.

Although the invention has been explained in relation to its preferred embodiment, it is to be understood that many other possible modifications and variations can be made without departing from the spirit and scope of the invention as hereinafter claimed.

What is claimed is:

1. A solar processing unit for the conversion of solar energy to electric power comprising:
a metal base;
a p-type layer of hexagonal boron nitride being deposited on the metal base;
a layer of graphene being deposited on the p-type layer of hexagonal boron nitride;
an n-type layer of hexagonal boron nitride being deposited on the layer of graphene;
the layer of graphene sandwiched between the p-type layer of hexagonal boron nitride and the n-type layer of hexagonal boron nitride forming a heterostructure; and
the n-type layer of hexagonal boron nitride being configured to be closer to a surface struck by sunlight than the p-type layer of hexagonal boron nitride.

2. The solar processing unit in claim 1, wherein a first insulating layer of hexagonal boron nitride is interjected between the p-type layer of hexagonal boron nitride and the layer of graphene, and wherein a second insulating layer of hexagonal boron nitride is interjected between the n-type layer of hexagonal boron nitride and the layer of graphene.

3. The solar processing unit in claim 1, wherein the metal base is composed of nickel.

4. The solar processing unit in claim 1, wherein the p-type layer of hexagonal boron nitride is doped with boron or lithium.

5. The solar processing unit in claim 1, wherein the n-type layer of hexagonal boron nitride is doped with nitrogen or fluorine.

6. The solar processing unit in claim 1, wherein the metal base is electrically connected to a negative terminal of the solar processing unit.

7. The solar processing unit in claim 1, wherein the n-type layer of hexagonal boron nitride is implanted with a conductive layer, and wherein the conductive layer is electrically connected to a positive terminal of the solar processing unit.

8. The solar processing unit in claim 7, wherein the conductive layer is composed of gold.

9. The solar processing unit in claim 7, wherein a proximal surface of a lens is deposited on the conductive layer.

10. The solar processing unit in claim 9, wherein the metal base is configured to reflect impinging electromagnetic radiation towards the lens.

11. The solar processing unit in claim 9, wherein an anti-reflective coating is deposited on a distal surface of the lens.

12. The solar processing unit in claim 9, wherein the lens is composed of borosilicate flat float glass.

13. The solar processing unit in claim 9, wherein a thickness of the lens ranges from a minimum of 0.7 mm to a maximum of 1.1 mm.

14. The solar processing unit in claim 1, wherein the layer of graphene is a monolayer of graphene, a bilayer of graphene, or a quadlayer of graphene.

15. A solar processing unit for the conversion of solar energy to electric power comprising:
a metal base;
the layer of graphene being bifurcated into a first graphene portion and a second graphene portion;
a p-type layer of hexagonal boron nitride being deposited on the first graphene portion;
the p-type layer of hexagonal boron nitride being implanted with a first conductive layer;
the first conductive layer being electrically connected to a negative terminal of the solar processing unit;
an n-type layer of hexagonal boron nitride being deposited on the second graphene portion;
the n-type layer of hexagonal boron nitride being implanted with a second conductive layer;
the second conductive layer being electrically connected to a positive terminal of the solar processing unit;
the first conductive layer and the second conductive layer being deposited on a proximal surface of a lens;
the first graphene portion, the p-type layer of hexagonal boron nitride, and the first conductive layer being electrically isolated from the second graphene portion, the n-type layer of hexagonal boron nitride, and the second conductive layer;
the first graphene portion, the p-type layer of hexagonal boron nitride, and the first conductive layer being positioned adjacent to the second graphene portion, the n-type layer of hexagonal boron nitride, and the second conductive layer; and
the first graphene portion and the second graphene portion being electrically connected to each other by the metal base.

16. The solar processing unit in claim 15, wherein a first insulating layer of hexagonal boron nitride is interjected between the p-type layer of hexagonal boron nitride and the first graphene portion, and a second insulating layer of hexagonal boron nitride is interjected between the n-type layer of hexagonal boron nitride and the second graphene portion.

17. The solar processing unit in claim 16, wherein the solar processing unit is configured to apply a forward bias voltage ranging from a minimum of 4 volts to a maximum of 5 volts across the metal base, thereby elevating a base voltage through the first graphene portion, the p-type layer of hexagonal boron nitride, the first conductive layer, and the metal base to resonate a bandgap of the p-type layer of hexagonal boron nitride in order to collect the available UV-A portion, the available UV-B portion, and the available UV-C portion of the solar spectrum, and thereby elevating the base voltage through the second graphene portion, the n-type layer of hexagonal boron nitride, the second conductive layer, and the metal base to resonate a bandgap of the n-type layer of hexagonal boron nitride in order to collect the available UV-A portion, the available UV-B portion, and the available UV-C portion of the solar spectrum.

18. The solar processing unit in claim 15, wherein an anti-reflective coating is deposited on a distal surface of the lens.

19. The solar processing unit in claim 18, wherein the anti-reflective coating is configured to transmit 20% of the available UV-A portion of the solar spectrum, transmit 80% of the available UV-B portion of the solar spectrum, or transmit 90% of the available UV-C portion of the solar spectrum.

20. The solar processing unit in claim 15, wherein the metal base is composed of gold.

21. The solar processing unit in claim 15, wherein the metal base is configured as a conductive backgate bridge.

22. The solar processing unit in claim 15, wherein the first conductive layer and the second conductive layer are composed of gold.

23. The solar processing unit in claim 15, wherein the first conductive layer and the second conductive layer are patterned with a plurality of fingers, and wherein the plurality of fingers covers a minimum of 5% of the total surface area of the proximal surface to a maximum of 25% of the total surface area of the proximal surface.

24. The solar processing unit in claim 23, wherein the plurality of fingers covers 15% of the total surface area of the proximal surface, and wherein the plurality of fingers is 301 fingers, and wherein each of the plurality of fingers is 14 millimeters in length and 15 micrometers in width, and wherein the plurality of fingers is spaced 85 micrometers apart from each other.

25. The solar processing unit in claim 15, wherein, wherein the p-type layer of hexagonal boron nitride is doped with boron or lithium.

26. The solar processing unit in claim 15, wherein the n-type layer of hexagonal boron nitride is doped with nitrogen or fluorine.

27. The solar processing unit in claim 15, wherein the metal base is electrically connected to a negative terminal of the solar processing unit.

28. The solar processing unit in claim 15, wherein the layer of graphene is a monolayer of graphene, a bilayer of graphene, or a quadlayer of graphene.

29. The solar processing unit in claim 15, wherein the metal base is configured to reflect impinging electromagnetic radiation towards the lens.

30. The solar processing unit in claim 15, wherein the lens is composed of borosilicate flat float glass.

31. The solar processing unit in claim 15, wherein a thickness of the lens ranges from a minimum of 0.7 mm to a maximum of 1.1 mm.
